(19) United States
(12) Patent Application Publication
(10) Pub. No.: US 2024/0352585 A1
(43) Pub. Date: Oct. 24, 2024

(54) SUPPORT SOCKET AND METHOD FOR MANUFACTURING PARTS USING SUPPORT SOCKET

(71) Applicant: KNJ CO.,LTD, Asan-si (KR)

(72) Inventors: Bun-hei KOO, Seoul (KR); Sung-ho LEE, Daegu (KR); Hyeon-jun CHO, Cheongju-si (KR)

(21) Appl. No.: 18/684,374

(22) PCT Filed: Jul. 14, 2022
(86) PCT No.: PCT/KR2022/010279

§ 371 Date: Feb. 16, 2024

(30) Foreign Application Priority Data
Aug. 24, 2021 (KR) 10-2021-0111538

(51) Int. Cl. C23C 16/458; C23C 16/32; C23C 16/56; H01L 33/00

(52) U.S. Cl. CPC C23C 16/4583; C23C 16/325; C23C 16/4581; C23C 16/56; H01L 33/0054

(57) ABSTRACT

The present invention relates to a support socket and a method for manufacturing a part having a deposited layer using the support sockets. A support socket according to one embodiment of the present invention, which consists of a top surface, a bottom surface, and side surfaces connecting the top surface and the bottom surface to each other, comprises: a groove formed on the bottom surface toward the top surface; and a machining reference surface as a plane forming the bottom of the groove.

### CROSS-REFERENCE TO RELATED APPLICATIONS

This is a national phase application under 35 U.S.C. § 371 of International Application No. PCT/KR2022/010279 filed Jul. 14, 2022, entitled “SUPPORT SOCKET AND METHOD FOR MANUFACTURING PARTS USING SUPPORT SOCKET,” which claims the benefit of and priority to KR Patent Application No. 10-2021-0111538 filed Aug. 24, 2021, the contents of both of which being incorporated by reference in their entireties herein.

### TECHNICAL FIELD

The present disclosure relates to a support socket and a method for manufacturing a part using the same. The present disclosure more specifically relates to a support socket for supporting a substrate in a deposition process and a method for manufacturing a part using the same.

### BACKGROUND

Generally, a susceptor serves to support a wafer during oxidation, deposition, and GaN Epitaxy or Sic Epitaxy of a light-emitting diode (LED) manufacturing process or semiconductor manufacturing process.

To improve the life time of the susceptor made from quartz, Si, and graphite or to prevent the product properties or yield from being deteriorated due to the occurrence of foreign substances, recently, such a susceptor has been changed to a susceptor made from SiC.

The susceptor that is made by coating SiC onto a graphite substrate by means of chemical vapor deposition (CVD) has an irregular flatness after the coating, because of the deformation of the substrate at a high temperature, thereby causing the properties and yield of the wafer to become deteriorated.

To solve such problems, a new method is proposed so that SiC grows on a graphite substrate to a high thickness, and after the surface of the grown SiC is machined, a product is finished.

However, as shown in FIG. 1, the graphite substrate placed on jigs may move in a deposition process, and since the graphite substrate is coated with SiC, an internal arranged state of the substrate may be not checked. Therefore, a deviation in the thickness of SiC may occur according to cutting positions in a machining process, and in some cases, as shown in FIG. 2, the graphite substrate may be exposed to the outside.

### BRIEF SUMMARY

It is an object of the present disclosure to provide a support socket for supporting a substrate in a deposition process and a method for manufacturing a part having a deposited layer using such support sockets.

It is another object of the present disclosure to provide a support socket fixedly inserted into a substrate and a method for manufacturing a part having a deposited layer using such support sockets.

It is yet another object of the present disclosure to provide a support socket having a groove adapted to insert a support pin thereinto and a machining reference surface located inside the groove and a method for manufacturing a part having a deposited layer using such support sockets.

It is still another object of the present disclosure to provide a support socket having a machining reference surface not exposed to the outside in a deposition process and a method for manufacturing a part having a deposited layer using such support sockets.

It is another object of the present disclosure to provide a support socket made from a material made in the same or similar environmental conditions as or to a deposition material coated onto a substrate and a method for manufacturing a part having a deposited layer using such support sockets.

The above-mentioned objects and other objects are accomplished by means of a support socket and a method for manufacturing a part having a deposited layer using such support sockets.

According to one aspect of the present disclosure, there is provided a support socket having a top surface, a bottom surface, and side surfaces connecting the top surface and the bottom surface to each other, the support socket including: a groove formed on the bottom surface toward the top surface; and a machining reference surface as a plane forming the bottom of the groove.

The top surface may be a plane and the machining reference surface may be parallel to the top surface.

At least a portion of each side surface may be a vertical surface with respect to the top surface, and the vertical surface may be located on a portion connected to the top surface.

A central axis of the groove may be located on a central axis of the support socket.

The support socket may be entirely made from SiC.

According to another aspect of the present disclosure, there is provided a method for manufacturing a part having a deposited layer, the method including: a substrate preparation step of preparing a substrate having at least two or more support grooves formed on the underside thereof; a support socket coupling step of inserting the top surfaces of the support sockets according to one embodiment of the present disclosure into the support grooves; a support pin insertion step of inserting support pins into the grooves of the support sockets; a deposition step of coating a coupled body of the substrate and the support sockets with a deposition material to form a deposited layer; a support pin separation step of separating the coupled body with the deposited layer from the support pins; and a machining step of removing portions of the deposited layer and portions of the support sockets.

In the machining step, cutting surfaces may be determined to remove the portions of the support sockets with respect to the grooves of the support sockets.

In the machining step, the cutting surfaces may be determined with respect to the machining reference surfaces of the support sockets.

The substrate may be a graphite substrate, the deposition material may be SiC, and each support socket may be made from the same SiC as the deposition material.

In the support socket coupling step, the support sockets may be inserted into the support grooves in such a way as to allow a vertical distance between the underside of the substrate and the machining reference surface of each support socket to be greater than a predetermined thickness of the deposited layer.

In the machining step, the portions of the deposited layer and the support sockets may be removed in such a way as to allow the predetermined thickness of the deposited layer to be 0.01 to 1 times greater than a thickness of the substrate.

The support socket according to the present disclosure prevents the substrate from moving with respect to the support pins during the deposition process.

Further, the support socket according to the present disclosure is provided with the machining reference surface not exposed to the outside during the deposition process, so that after the deposition, the position of the substrate with respect to the machining reference surface is accurately recognized.

Furthermore, the method for manufacturing the part having the deposited layer according to the present disclosure is capable of manufacturing the part having the deposited layer with a desired thickness using the recognized position of the substrate.

In addition, the support socket according to the present disclosure is made from the material having the same conditions as the deposition material coated onto the substrate, so that even if a portion of the support socket is not removed after the deposition process, the remaining support socket serves as the deposited layer.

### BRIEF DESCRIPTION OF DRAWINGS

FIGS. 1 and 2 are schematic views showing problems occurring in conventional technologies.

FIG. 3 is a perspective view showing a support socket according to an embodiment of the present disclosure.

FIG. 4 is a sectional view showing the support socket according to the embodiment of the present disclosure.

FIG. 5 is sectional view showing support sockets according to other embodiments of the present disclosure.

FIG. 6 is a flowchart showing a method for manufacturing a part according to an embodiment of the present disclosure.

FIG. 7 is a sectional view showing a substrate prepared in a substrate preparation step of the method for manufacturing the part according to the embodiment of the present disclosure.

FIG. 8 is a sectional view showing a state where the substrate and support sockets are coupled to each other in a support socket coupling step of the method for manufacturing the part according to the embodiment of the present disclosure.

FIG. 9 is a sectional view showing a state where support pins are inserted into grooves of the support sockets in a support pin insertion step of the method for manufacturing the part according to the embodiment of the present disclosure.

FIG. 10 is a sectional view showing a state where a deposition material is coated onto a coupled body of the substrate and the support sockets to form a deposited layer in a deposition step of the method for manufacturing the part according to the embodiment of the present disclosure.

FIG. 11 is a sectional view showing a state where the support pins are separated from the coupled body of the substrate and the support sockets on which the deposited layer is formed in a support pin separation step of the method for manufacturing the part according to the embodiment of the present disclosure.

FIG. 12 is a sectional view showing cutting surfaces determined with respect to the grooves of the support sockets in a machining step of the method for manufacturing the part according to the embodiment of the present disclosure.

FIG. 13 is a sectional view showing the part finally produced by the method for manufacturing the part according to the embodiment of the present disclosure.

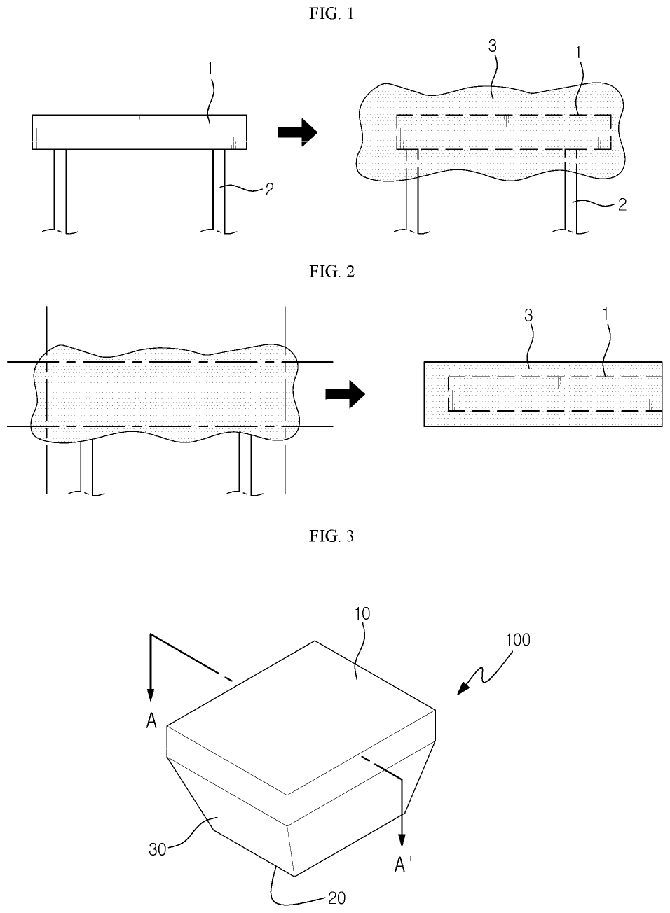

### DETAILED DESCRIPTION

Hereinafter, an explanation of a support socket and a method for manufacturing a part having a deposited layer using support sockets according to the present disclosure will be given in detail with reference to the accompanying drawings.

In the description, only the explanations needed to allow a support socket and a method for manufacturing a part having a deposited layer using support sockets according to the present disclosure to be understood will be given, and other explanations making the scope of the present disclosure not clear will be avoided.

Terms used in the present disclosure are to be given their ordinary and customary meaning to a person of ordinary skill in the art, and are not to be limited to a special or customized meaning unless expressly so defined herein.

In the description, when it is said that one portion is described as “includes” any component, one element further may include other components unless no specific description is suggested.

In the description of the present disclosure, it should be understood that the terms “center”, “upper”, “lower”, “front”, “rear”, “left”, “right”, “vertical”, “horizontal”, “top”, “bottom”, “inner”, “outer”, and other indicated orientations or positional relationships are based on the orientations or positional relationships shown in the attached drawings, which are conveniently used only to briefly explain the present disclosure, and therefore, an indicated device or component does not have any specific orientation or does not operate in any specific orientation. Accordingly, the present disclosure may not be limited by the above-mentioned terms.

In various embodiments of the present disclosure, a representative embodiment will be explained using the same reference numerals representing the same components having the same configurations, and configurations different from one embodiment in other embodiments will be explained.

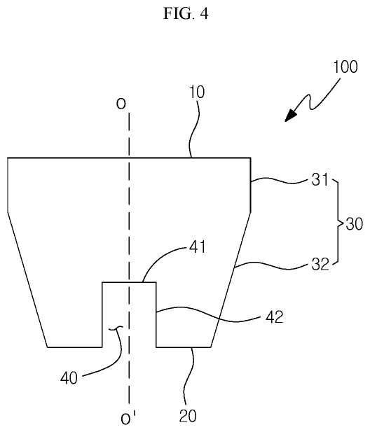

FIG. 3 is a perspective view showing a support socket 100 according to an embodiment of the present disclosure and FIG. 4 is a sectional view taken along the line A-A of FIG. 3.

The support socket 100 according to an embodiment of the present disclosure serves to connect a substrate and a support pin to prevent the substrate from moving above the support pin in a deposition process.

In detail, as shown in FIGS. 3 and 4, the support socket 100 according to the embodiment of the present disclosure includes a top surface 10, a bottom surface 20, and side surfaces 30 connecting the top surface 10 and the bottom surface 20 to each other.

The top surface 10 of the support socket 100 according to the embodiment of the present disclosure has a larger area than the bottom surface 20. Therefore, the side surfaces 30 connecting the top surface 10 and the bottom surface 20 to each other are slantly formed between the top surface 10 and the bottom surface 20.

However, the top surface 10 of the support socket 100 according to the embodiment of the present disclosure is inserted into a support groove of the substrate in a method for manufacturing a part having a deposited layer according to an embodiment of the present disclosure as will be discussed later. To allow the top surface 10 to be fixedly inserted into the support groove of the substrate with ease, accordingly, each side surface 30 of the support socket 100 desirably has a vertical surface 31 extending vertically from the top surface 10 and a slant surface 32 tapered from the vertical surface 31 toward the bottom surface 20, as shown in FIG. 4.

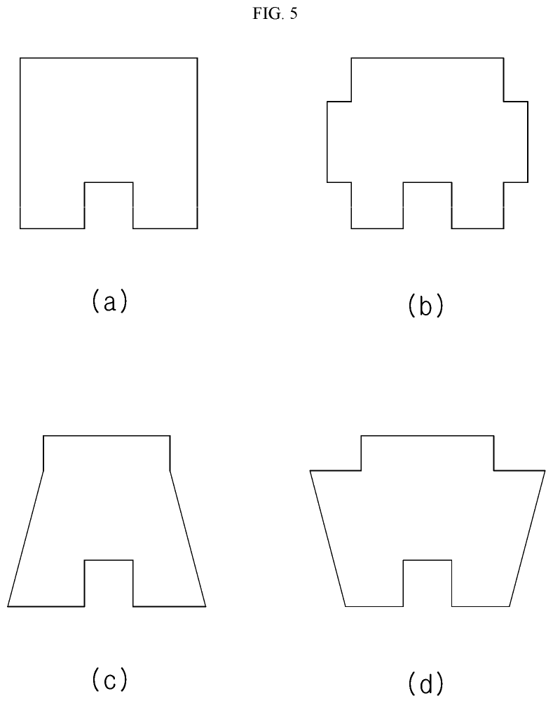

Further, the support socket 100 according to the embodiment of the present disclosure is not limited to the shape as shown in FIGS. 3 and 4, and as shown in FIG. 5, accordingly, the top surface 10 may have the same area as the bottom surface 20 or may have a smaller area than the bottom surface 20.

Even in the case, however, portions of the side surfaces 30 connected with the top surface 10 are vertical surfaces with respect to the top surface 10 in consideration of the insertion of the top surface 10 of the support socket 100 into the support groove of the substrate.

The support socket 100 according to the embodiment of the present disclosure includes a groove 40 formed on the bottom surface 20 toward the top surface 10.

The groove 40 is a reference for determining a cutting surface of the deposited layer in a machining step of the method for manufacturing a part having a deposited layer according to an embodiment of the present disclosure as will be discussed later.

To do this, desirably, a central axis of the groove 40 is positioned at a central axis O-O′ of the support socket 100 according to the embodiment of the present disclosure.

Further, desirably, the groove 40 has side surfaces 42 vertical with respect to a machining reference surface 41 and symmetrical with respect to the central axis O-O′ of the support socket 100.

The machining reference surface 41 as the bottom surface of the groove 40 is plane as a reference surface for determining the cutting surface of the deposited layer in the machining step of the method for manufacturing a part having a deposited layer according to an embodiment of the present disclosure as will be discussed later, and desirably, the machining reference surface 41 is a plane parallel to the top surface 10.

A portion of the support socket 100 according to the embodiment of the present disclosure remains in the part having the deposited layer as a final product, and accordingly, the support socket 100 according to the embodiment of the present disclosure is made from the same material as a deposition material used in producing the part having the deposited layer according to the embodiment of the present disclosure. That is, if SiC is coated onto a graphite substrate to form a deposited layer, the support socket 100 is desirably made from SiC.

Further, the support socket 100 according to the embodiment of the present disclosure is made in a similar environment to an environment in the deposition step for the part having the deposited layer, so that the grain sizes of particles constituting the support socket 100 are desirably similar to those of the deposited layer.

Up to now, the support socket 100 according to the embodiment of the present disclosure has been explained. Now, the method for manufacturing a part having a deposited layer using such support sockets according to an embodiment of the present disclosure will be described.

Embodiments of the present disclosure as will be discussed later will be explained with reference to the flowchart suggested in the drawings. To provide brief description, a method according to an embodiment of the present disclosure is suggested with a series of blocks, but the present disclosure may not be limited to the order of the blocks. For example, some blocks may occur in the order different from the order shown and described in the present disclosure or simultaneously together with other blocks. Further, various different branches, flow paths, and orders of the blocks for accomplishing the same or similar results may be executed. Moreover, all of the blocks shown may not be required in performing the method as described in the present disclosure, and some of the blocks may be selectively used within the scope of the present disclosure, combined to a smaller number, or increase with additional blocks.

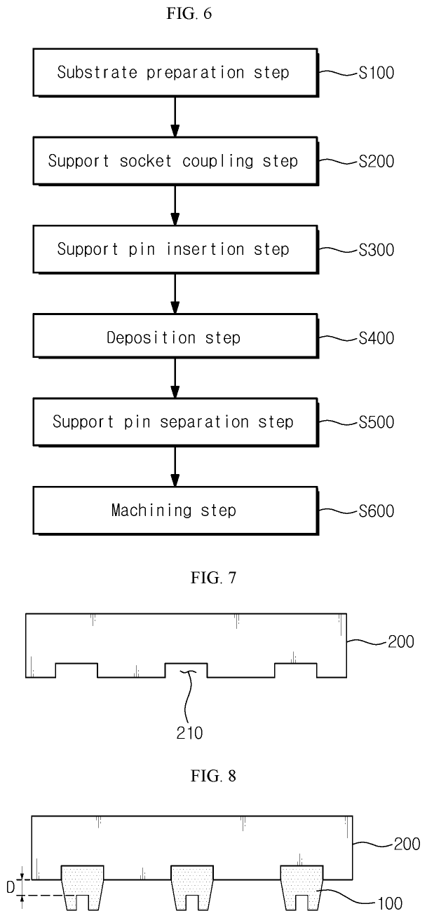

FIG. 6 is a flowchart showing a method for manufacturing a part according to an embodiment of the present disclosure.

As shown in FIG. 6, the method for manufacturing a part having a deposited layer according to an embodiment of the present disclosure includes a substrate preparation step S100, a support socket coupling step S200, a support pin insertion step S300, a deposition step S400, a support pin separation step S500, and a machining step S600.

First, the substrate preparation step S100 is the process of preparing a substrate to be subjected to machining. Generally, a part such as a wafer carrier used in a process of manufacturing a semiconductor or LED has a deposited layer formed by coating SiC (silicon carbide) onto a graphite substrate. A part may consist of only SiC, without any substrate, but if the substrate is used, the time required for manufacturing the part is greatly reduced.

Therefore, the substrate for forming the deposited layer is prepared in the method for manufacturing the part having the deposited layer according to the embodiment of the present disclosure.

Unlike the conventional methods, however, the method for manufacturing the part having the deposited layer according to the embodiment of the present disclosure includes the substrate preparation step S100 in which a substrate 200 having support grooves 210 formed on the underside thereof is prepared, as shown in FIG. 7.

The support grooves 210 of the substrate 200 serve to insert the support sockets 100 according to the embodiment of the present disclosure thereinto. To allow the top surfaces 10 of the support sockets 100 to be inserted into the support grooves 210, the support grooves 210 have the corresponding shapes and sectional areas to the top surfaces 10 of the support sockets 100.

Further, the support grooves 210 are formed in fixed position. For example, the central axis of the support groove located at the leftmost position of the substrate is formed at a determined distance S from the left end point of the substrate, and the central axis of the support groove located at the rightmost position of the substrate is formed at a determined distance S from the right end point of the substrate.

Further, two or more support grooves 210 are desirably formed so that the substrate 200 is stably supported against the support sockets 100.

Furthermore, the plurality of support grooves 210 are uniformly and symmetrically formed on the substrate.

Next, the support socket coupling step S200 is the process of coupling the support sockets 100 to the substrate 200.

In the support socket coupling step S200, as shown in FIG. 8, the top surfaces of the support sockets 100 are inserted into the support grooves 210 formed on the underside of the substrate 200, so that the support sockets 100 are coupled to the substrate 200.

The areas of the top surfaces of the support sockets, that is, the areas formed with the top surfaces 10 and the vertical surfaces 31 of the support sockets are inserted into the support grooves 210 of the substrate 200.

In this case, each support socket 100 is inserted into the support groove 210 in such a way as to allow a vertical distance D between the underside of the substrate and the machining reference surface 41 of each support socket to be greater than a predetermined thickness of the deposited layer.

After that, the support pin insertion step S300 is the process of inserting support pins 300 into the grooves of the support sockets 100.

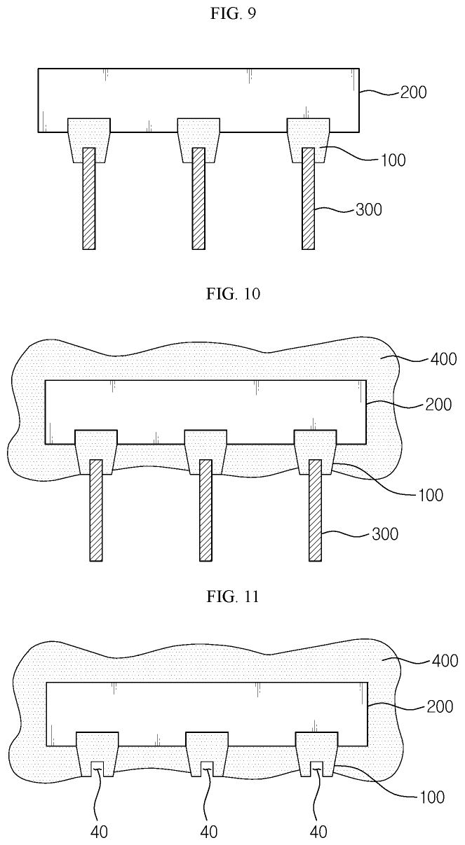

As mentioned above, the support socket 100 according to the embodiment of the present disclosure has the groove 40 formed on the bottom surface thereof, and in the support pin insertion step S300, as shown in FIG. 9, the support pins 300 are inserted into the grooves 40 of the support sockets 100.

The insertion of the support pins 300 into the grooves 40 of the support sockets 100 enables a coupled body of the substrate and the support sockets to be located in CVD equipment and prevents a deposition material from being coated onto the grooves 40 of the support sockets 100 in the deposition step as will be discussed later.

Next, the deposition step S400 is the process of coating a deposition material onto the coupled body of the substrate and the support sockets.

The coupled body of the substrate and the support sockets, which is located in the CVD equipment through the support pin insertion step S300, is coated with the deposition material through chemical vapor deposition (CVD).

To improve the flatness of the deposited layer in the method for manufacturing the part having the deposited layer according to the embodiment of the present disclosure, a portion of the deposited layer coated onto the substrate 200 is removed in the machining step as will be discussed later. In the deposition step S400, accordingly, the deposited layer 400 grows to a relatively high thickness (e.g., a thickness of 2 mm or more and otherwise a thickness of 0.01 to 1 times greater than a thickness of the substrate 200).

As shown in FIG. 10, in the method for manufacturing the part having the deposited layer according to the embodiment of the present disclosure, the support sockets 100 according to the present disclosure are coupled to the support grooves 210 of the substrate 200, and the support pins 300 are inserted into the grooves of the support sockets 100. Unlike the conventional technologies, accordingly, the positions of the substrate 200 with respect to the support pins 300 or the support sockets 100 are not changed at all.

Next, the support pin separation step S500 is the process of separating the support pins 300 from the coupled body of the substrate 200 and the support sockets 100 onto which the deposited layer 400 is formed.

As shown in FIG. 11, the deposition material is coated onto both of the substrate and the support sockets in the deposition step S400, but the grooves 40 of the support sockets, into which the support pins 300 are inserted, are prevented from being coated with the deposition material by means of the support pins 300.

After the deposition step, if the support pins 300 are separated from the coupled body of the substrate 200 and the support sockets 100 onto which the deposited layer 400 is formed in the support pin separation step S500, the grooves 40 of the support sockets are exposed to states where no deposition material is coated thereonto.

Accordingly, the substrate is covered with the deposition material, but the positions of the support grooves of the substrate and the positions of the grooves of the support sockets are recognized by a user. Therefore, the position of the substrate with respect to the grooves is recognized by the user.

Next, the machining step S600 is the process of removing given portions of the deposited layer 400 and the support sockets 100 to finish the part having the deposited layer.

The deposited layer produced in the deposition step is not flat on the surface thereof, and to allow the outer surfaces of the finished part to be flattened, accordingly, the given portions of the deposited layer 400 and the support sockets 100 are removed in the machining step S600.

In this case, if the position of the substrate is wrongly recognized, as shown in FIG. 2, the substrate is exposed, and otherwise, the thickness of the deposited layer is not uniform according to its position.

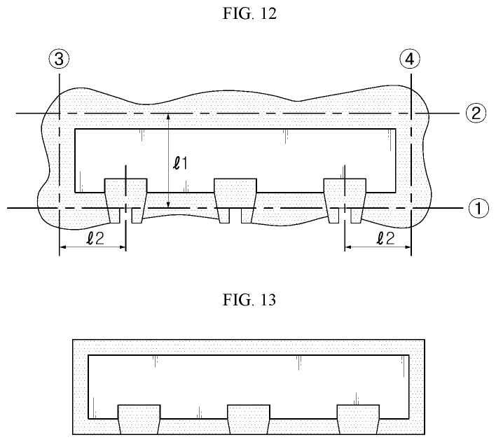

In the method for manufacturing the part according to the embodiment of the present disclosure, the positions of the support grooves of the substrate and the positions of the grooves of the support sockets are recognized by the user, and therefore, cutting surfaces with respect to the grooves are determined by the user, as shown in FIG. 12.

That is, a bottom cutting surface \textcircled{1} is determined in consideration of a vertical distance D between the underside of the substrate and the machining reference surface 41 and the predetermined thickness of the deposited layer.

If the vertical distance D is the same as the predetermined thickness of the deposited layer, the plane connecting the machining reference surfaces 41 of the plurality of support sockets is determined as the bottom cutting surface \textcircled{1} by the user.

Next, a distance [symbol] 1 from the machining reference surface 41 of the support socket to a top cutting surface \textcircled{2} is determined using the thickness of the substrate and the predetermined thickness of the deposited layer, and accordingly, the top cutting surface \textcircled{2}, which is spaced apart from the determined bottom cutting surface \textcircled{1} by the distance [symbol] 1 and horizontal with respect to the bottom cutting surface \textcircled{1}, is thus determined.

Further, a distance [symbol] 2 from the central axis of the groove of the support socket 100 located at the outermost position of the substrate to a side cutting surface is determined using distance information between the central axis of the support groove formed at the leftmost or rightmost position of the substrate and the side surface of the substrate and the predetermined thickness of the deposited layer, and accordingly, left and right side cutting surfaces \textcircled{2}, which are spaced apart from the central axes of the grooves of the support sockets 100 located at the outermost positions of the substrate by the distance [symbol] 2 and vertical with respect to the bottom cutting surface \textcircled{1}, are thus determined.

Furthermore, front and rear cutting surfaces, which are not shown, may be determined in the same method as mentioned above.

A portion of the deposited layer 400 is removed along the determined cutting surfaces, and further, a portion of the deposited layer 400 and portions of the support sockets 100 are removed along the bottom cutting surface, so that as shown in FIG. 12, the finished part has the deposited layer 400 with the predetermined thickness formed on every surface of the substrate 200.

For example, the thickness of the deposited layer is 0.01 to 1 times greater than the thickness of the substrate over every surface of the substrate.

As shown in FIG. 13, portions of the support sockets remain in the finished part, and as mentioned above, the support socket 100 is made from the same material as the deposition material. That is, if SiC is coated onto a graphite substrate to form the deposited layer, the support socket 100 is desirably made from SiC.

Further, the support socket 100 is made in a similar environment to an environment in the deposition step, so that the grain sizes of particles constituting the support socket 100 are desirably similar to those of the deposited layer.

Up to now, the support socket and the method for manufacturing the part having the deposited layer using the support sockets according to the embodiments of the present disclosure have been explained. However, this does not limit the disclosure within specific embodiments and it should be understood that the disclosure covers all the modifications, equivalents, and replacements within the idea and technical scope of the disclosure.

1. A support socket having a top surface, a bottom surface, and side surfaces connecting the top surface and the bottom surface to each other, the support socket comprising: a groove formed on the bottom surface toward the top surface; and a machining reference surface as a plane forming the bottom of the groove.

2. The support socket according to claim 1, wherein the top surface is a plane and the machining reference surface is parallel to the top surface.

3. The support socket according to claim 2, wherein at least a portion of each side surface is a vertical surface with respect to the top surface, and the vertical surface is located on a portion connected to the top surface.

4. The support socket according to claim 1, wherein a central axis of the groove is located on a central axis of the support socket.

5. The support socket according to claim 1, wherein the support socket is entirely made from SiC.

6. A method for manufacturing a part having a deposited layer, the method comprising:
a substrate preparation step of preparing a substrate having at least two or more support grooves formed on the underside thereof;
a support socket coupling step of inserting the top surfaces of the support sockets according to claim 1 into the support grooves;
a support pin insertion step of inserting support pins into the grooves of the support sockets;
a deposition step of coating a coupled body of the substrate and the support sockets with a deposition material to form a deposited layer;
a support pin separation step of separating the coupled body with the deposited layer from the support pins; and
a machining step of removing portions of the deposited layer and portions of the support sockets.

7. The method according to claim 6, wherein in the machining step, cutting surfaces are determined to remove the portions of the support sockets with respect to the grooves of the support sockets.

8. The method according to claim 7, wherein in the machining step, the cutting surfaces are determined with respect to the machining reference surfaces of the support sockets.

9. The method according to claim 6, wherein the substrate is a graphite substrate, the deposition material is SiC, and each support socket is made from the same SiC as the deposition material.

10. The method according to claim 6, wherein in the support socket coupling step, the support sockets are inserted into the support grooves in such a way as to allow a vertical distance between the underside of the substrate and the machining reference surface of each support socket to be greater than a predetermined thickness of the deposited layer.

11. The method according to claim 6, wherein in the machining step, the portions of the deposited layer and the support sockets are removed in such a way as to allow the predetermined thickness of the deposited layer to be 0.01 to 1 times greater than a thickness of the substrate.
